(19) United States
(12) Patent Application Publication
(10) Pub. No.: US 2010/0295586 A1
(43) Pub. Date: Nov. 25, 2010

(54) PLL INTEGRAL CONTROL

(75) Inventor: Nicholas Weiner, Bristol (GB)

Correspondence Address: MACMILLAN SOBANSKI & TODD, LLC, ONE MARITIME PLAZA FIFTH FLOOR, 720 WATER STREET, TOLEDO, OH, 43604-1619, US

(73) Assignee: Xintronix Limited, Bristol (GB)

(21) Appl. No.: 12/780,232

(22) Filed: May 14, 2010

(30) Foreign Application Priority Data
May 20, 2009 (GB) 0908764.4
Jun. 3, 2009 (GB) 0909572.0

(51) Int. Cl. H03L 7/08

(52) U.S. Cl. 327/157

(57) ABSTRACT

A phase locked loop has an integral control path, in which digital representations of phase error are added over successive time intervals, and a charge pump circuit is configured to charge or discharge an integrating capacitor according to successive resultant sum values, with a voltage on the integrating capacitor used to control an output frequency of a controlled oscillator in the phase locked loop.

### BACKGROUND OF THE INVENTION

In a digital communications receiver, a clock signal, synchronous with the data, is required to sample the received waveform. The clock signal itself often has also to be recovered from the received waveform. This is referred to as clock recovery. Modern communication electronics make use of phase locked loops (PLL) for this purpose.

High frequency signals are derived in communication, and other applications, using a PLL for frequency multiplication, which is also referred to as frequency synthesis.

FIG. 1 shows a representation of the signal processing performed by the elements of a PLL as used for clock recovery. On transitions of the received waveform at input 101, the phase detector 102 produces an output 103 according to the phase error between the transition and a selected edge (either rising or falling) of the recovered clock signal 110 from VCO 109. In lock, the recovered clock will be synchronous with the received waveform and with average phase such that the selected edges are aligned with the waveform transitions. 104 represents the signal processing performed upon the phase detector output 103 for control of the VCO. The signal processing of 104 may be implemented by a “loop filter.” 105 and 106 represent the proportional and integrating control aspects with outputs proportional to phase detector output 103 and to its integral, respectively. 107 represents the summing of the proportional and integral controls to provide signal processing output signal, 108, which controls the VCO.

In the descriptions of this document, the terms “Voltage Controlled Oscillator” and “Controlled Oscillator” and abbreviation VCO are all used to mean an oscillator having frequency controlled by an input variable which, in an implementation, may be either a voltage or a current.

FIG. 2 shows a representation of the signal processing performed by the elements of a PLL as used for frequency multiplication. On transitions of the reference signal at input 201, the phase detector 202 produces an output 203 according to the phase error between the transition and a corresponding edge of the signal 212, which is the frequency multiplier output 210 from VCO 209 divided down by frequency divider 211. In lock, the synthesized signal will be synchronous with the reference signal and have frequency N (the divide ratio) times larger. 204 represents the signal processing performed upon the phase detector output 203 for control of the VCO. The signal processing of 204 may be implemented by a “loop filter.” 205 and 206 represent the proportional and integrating control aspects with outputs proportional to phase detector output 203 and to its integral, respectively. 207 represents the summing of the proportional and integral controls to provide signal processing output signal 208 which controls the VCO 209. For “fractional-N” frequency multiplication, the divide ratio N is changed over time, the average value corresponding to the desired non-integer frequency multiplication ratio.

The loop filter elements of FIG. 1 and FIG. 2 represent the voltage controlled oscillator (VCO) control functionality situated between the phase detector outputs 102 and 203 and the VCO inputs 108 and 208, respectively. The zero-frequency pole introduced by the integrating control function is required to ensure that the steady-state phase error is zero, as required for optimum phase detector performance. The VCO also introduces a zero-frequency pole into the open loop phase gain characteristic. For stability, a zero is also required. This is achieved by the inclusion, in the filter functionality, of the proportional gain control paths 105 and 205, as well as the integrating control paths 106 and 206. In the signal processing representations of FIG. 1 and FIG. 2, the outputs of the integrating and proportional portions of the control functionality are shown combined prior to the VCO input. In an implementation, the outputs may be combined prior to the VCO or within the VCO element itself.

For ease of implementation and repeatability of performance, clock recovery and frequency multiplication PLLs may make use of binary-valued or “bang-bang” phase detectors. These phase detectors produce one of two possible “votes” at each transition of the received waveform. If the transition occurs before the clock edge, then the vote will be to speed UP the VCO. If the transition occurs after the clock edge, then the vote will be to slow DOWN the VCO. In the absence of a transition, neither an UP nor a DOWN vote is cast. Conversely, in the absence of a transition, the previous phase error may be assumed to persist and a further, identical vote cast. The UP and DOWN signals together represent a binary-valued (sign only) phase error metric.

More generally, a digital phase error representation may make use of a number of bits, according to the degree of resolution represented.

For clock recovery and frequency multiplication, commonly used continuous-valued (or analog) phase detectors provide “Advance” and “Retard” pulses. For clock recovery, phase detectors (using methods similar to that disclosed by Hogge in U.S. Pat. No. 4,535,459) produce both Advance and Retard pulses on each phase detection event, with the property that the difference in their lengths represents the measured phase error. For frequency multiplication, widely used phase detectors provide either an Advance or a Retard pulse on each phase detection event, depending upon whether transition in the divided-down VCO output signal (212 of FIG. 2) comes before of after the corresponding transition of the reference signal (210 of FIG. 2).

An alternative continuous-valued phase measure may be obtained by sampling the magnitude of the received waveform using the VCO output edge to be aligned with input waveform transitions. Signal processing may be applied to cancel intersymbol interference from such waveform samples.

The frequency of oscillation of certain designs of VCO depend upon the supply voltage. The value of the supply voltage may therefore be used as the VCO frequency control input.

This invention addresses the implementation of the integrating control function, within a clock recovery or frequency multiplication PLL, making use of a digital phase error representation.

In the description, the terms “integral control” and “integrating control” are used interchangeably.

Prior art charge pump method: Chapter 12 of Phaselock Techniques by Floyd Gardner (Wiley, 2005) describes the use of charge pumps in phase locked loops. Phase errors are represented by pulses of current switched to either charge, or discharge, an integrating capacitor. If a binary-valued phase detector is used, only the sign of each current pulse (i.e. charging or discharging) depends upon the phase error detected. If a continuous-valued phase detector is used, the duration of each current pulse also depends upon the measured phase error. Such a current switching circuit is referred to as a “charge pump.” FIG. 3 shows a PLL with a charge pump 302 and integrating capacitor 309. At each phase detection event, the charge-pump style phase detector 302 delivers an output charge according to the phase error between the VCO output signal 311 and the received waveform or reference signal 301. The elements of 302 are the phase detection circuit 303 and the charge pump output circuits 304 and 305. 304 and 305 deliver charges of opposite polarities. For each phase detection event, the net charge delivered to output node 306 represents the phase error detected. Capacitor 309 performs the integrating control function by integrating the charge outputs delivered by 302. The voltage across the capacitor is the integrating control signal. The charge outputs from 302 flow through resistor 308 and, in doing so, develop a voltage across it. The voltage across the resistor is the proportional control signal. The voltage at node 306 is the required sum of the integral and proportional control signals and controls the VCO 310. Such PLLs are widely used for clock recovery and frequency multiplication.

A binary-valued phase detector will, in the desired steady-state, deliver UP and DOWN votes, with corresponding charging and discharging charge quanta, in equal proportions, one per phase detection event, and with no net capacitor charging/discharging intended. This implies that the UP and DOWN charges must be very well matched, i.e., the UP and DOWN currents, pulse durations, and pulse shapes must match very well. Generally, larger currents can be made to match more closely than very small currents.

U.S. Pat. Nos. 7,034,588 and 7,183,822 are among those disclosing improvements to the design of charge pump circuits to achieve the desired matching of the UP and DOWN current pulses.

The difficulty and power dissipation involved in achieving the necessary matching of the charge pump currents, and the performance impairments associated with mismatches, are limitations of conventional charge pump PLLs.

Digital integration method: U.S. Pat. Nos. 6,765,445 and 7,613,267 address the limitation of the charge pump method and describe, instead, the use of digital accumulation within a PLL to implement the integrating control function. This is illustrated in FIG. 4. In the FIG. 402 is the phase detector, comparing the phase of input signal 401 and output 420 of VCO 419. The output 403 from the phase detector is connected to both an integrating control path 404 and a separate proportional control path 421. The integrating control path comprises an analog to digital converter 405, a digital accumulator 407, a digital to analog converter 411, and a filter 413. The proportional control path comprises a gain element 415 and a filter 416. Summing element 418 sums the outputs of the integral and proportional control paths, the result being used to control VCO 419. The digital accumulator 407 comprises summing element 408 and register element 409.

The digital to analog conversion necessarily involves quantization steps. The steady-state performance will involve rapid switching between two adjacent values. This leads to the inclusion of the additional filter shown between the digital to analog converter and the VCO. The digital to analog converter and filter consume power and require silicon area, with associated cost implications.

### SUMMARY OF THE INVENTION

The present invention pertains to the integrating portion of a PLL control path. The invention makes use of a digital representation of phase errors and computes an average, or aggregate, phase error over successive measurement and control periods of time. Integral control is accomplished by charging or discharging an integrating capacitor according to the successive aggregate phase error results and by using the voltage on the integrating capacitor to control the frequency of the VCO.

Various aspects of this invention will become apparent to those skilled in the art from the following detailed description of the preferred embodiment, when read in light of the accompanying drawings.

### BRIEF DESCRIPTION OF THE DRAWINGS

FIG. 1 illustrates signal processing functions performed within a clock recovery phase-locked loop.

FIG. 2 illustrates signal processing functions performed within a frequency multiplier PLL.

FIG. 3 illustrates a phase locked loop with charge pump and loop filter for signal processing.

FIG. 4 illustrates a clock recovery phase-locked loop with digital integrator—Prior Art.

FIG. 5 illustrates an example embodiment of integrating control function according to the current invention.

FIG. 6 illustrates an implementation of vote accumulator using high-speed dividers.

FIG. 7 is an illustration of PLL using novel integral control path together with continuous-valued proportional control.

FIG. 8 is an illustration of PLL using novel integral control path together with continuous-valued proportional control.

FIG. 9 is an illustration of PLL using novel integral control path together with digital proportional control.

FIG. 10 illustrates a ring oscillator with supply voltage controlled by integral gain path.

FIG. 11 illustrates an example charge pump using switched capacitor method.

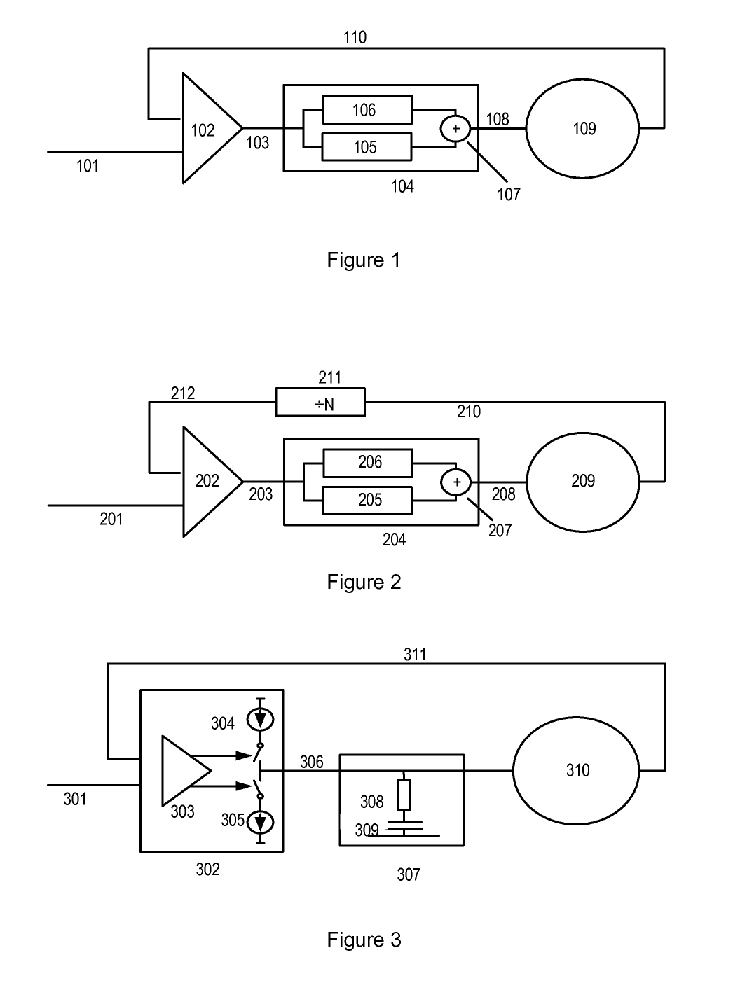

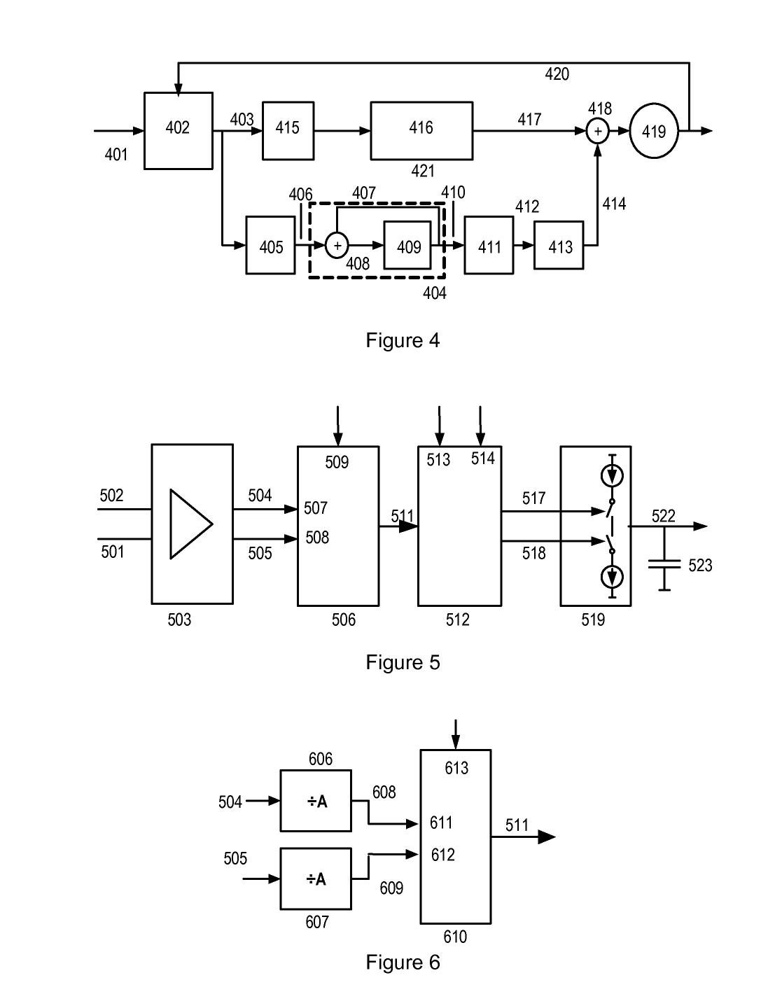

### DETAILED DESCRIPTION OF THE PREFERRED EMBODIMENT

FIG. 5 illustrates an embodiment of the invention, in this case using a bang-bang phase detector with its two binary-valued outputs to represent measured phase errors. The phase detector 503 has UP and DOWN output signals 504 and 505 which are connected to accumulator (or up-down counter) 506 with increment and decrement inputs 507 and 508 and reset input 509. The resultant count is computed over successive measurement time intervals. Each computation involves zeroing the counter accumulator at the start of the measurement interval, using reset input 509, and then counting UP and DOWN according to the phase errors measured within the interval.

At the end of each measurement interval, the resultant multi-bit value, at 511, represents the aggregate or average phase error, as measured over the interval. Subsequently, the resultant value is applied using duration counter 512 to charge pump 519 to charge or discharge integrating capacitor 523. The consequence of loading a value from 511 is that the magnitude is represented by the duration of a pulse at either 517 or 518, according to the sign of the value. 519 is a charge pump that delivers positive or negative charge to node 522 according to the input signals 517 and 518. Capacitor 523 integrates the charge delivered by the charge pump 519.

The charge pump may be implemented by switching a charging or discharging current to the integrating capacitor. The polarity (charging or discharging) depending upon the sign of the resultant count and for a period of time according to the magnitude of the resultant count.

The charge pump may alternatively be implemented using a switched capacitor method, such as that illustrated in FIG. 11. Either charging or discharging cycles are performed depending upon the sign of the resultant count and the number of charging or discharging cycles, depending upon the magnitude of the resultant count. In the example shown, the voltage at node 1105 is higher than that of integrating capacitor node 522 and the voltage at node 1109 is lower than that of integrating capacitor node 522. A charging cycle (i.e., incremental charging of capacitor 523) proceeds as follows. Switch 1103 is closed to charge node 1101 to the voltage of node 1105. Switch 1103 is then opened and then switch 1106 closed. When this occurs, charge is transferred from capacitor 1104 to capacitor 523. A discharging cycle (i.e., incremental discharging of capacitor 523) proceeds as follows. Switch 1107 is closed to charge node 1102 to the voltage of node 1109. Switch 1107 is then opened and then switch 1106 closed. When this occurs, charge is transferred from capacitor 523 to capacitor 1108. In general, a switched capacitor charge pump transfers charge to and from the integrating capacitor by switching connection to charge or discharge one or more, smaller capacitor.

Using either charge pump method, an implementation may make use of only the resultant sign to determine whether the capacitor is either incrementally charged or incrementally discharged during each integrating control cycle.

A phase detector may be used that provides a multi-bit phase error representation. If such a phase detector is used, the resultant may be computed as the sum, over each time interval, of the multi-bit phase error values.

The resultant aggregate, or average, phase error, as described above, may be computed using the digital phase error representations corresponding to all transitions of the input waveform, in the case of clock recovery, or reference signal, in the case of frequency multiplication, occurring within each measurement interval, or alternatively, corresponding to only a subset of the waveform transitions. For fractional-N frequency multiplication, the resultant may be computed using only divided-down VCO output signal transitions that are required to align with reference signal transitions.

The method disclosed here has the advantage that it is very tolerant to mismatches between the charging and discharging current pulses or charge quanta. This is because over each measurement period, cancellation of phase error values (i.e. UP and DOWN votes for the case of a bang-bang phase detector) is performed digitally. This allows very small charge quanta to be used and, hence, a small integrating capacitor. The approach has the advantage of allowing compact, and fully integrated, implementations having high performance and consuming very little power.

FIG. 6 illustrates that for the case of a bang-bang phase detector, making use of UP and DOWN voting signals, use may be made of high-speed divider circuits 606 and 607 connected to the phase detector UP and DOWN outputs 504 and 505. The divider outputs, 608 and 609, indicate the completion of divider cycles, which may be accumulated. For example, divide by 16 circuits (A=16) may be used to generate UP/16 and DOWN/16 signals. Accumulating these gives results approximately equal to the UP/DOWN vote resultant divided by 16. The dividers may be implemented using single direction counters, such as ripple counters. In the figure, signals 608 and 609 are connected to the increment and decrement inputs 611 and 612 of accumulator (up-down counter) 610. The accumulator has reset input 613 and signed output 511.

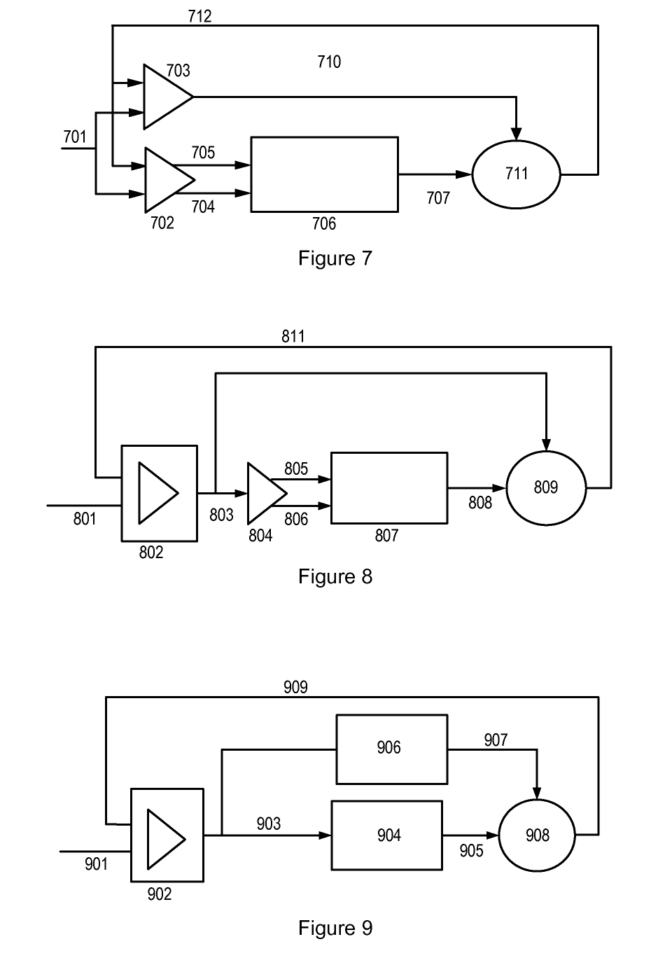

FIG. 7 illustrates the use of an integrating control path, according to the present invention, together with continuous-valued (or analog) proportional control path. The two control paths making use of separate phase detectors measure the phase relationship between input signal 701 and VCO output signal 712. The integrating control path 706 uses phase detector 702 with digital outputs 704 and 705. These may be binary valued UP and DOWN voting signals. More generally, a multi-bit digital representation of the phase error may be used. The integrating path has output 707. The proportional control path makes use of phase detector 703 with continuous-valued (or analog) output. The continuous-valued (or analog) phase error representation at 710 may make use of “Advance” and “Retard” pulse durations to represent phase errors. Signals at both 707 and 710 control the VCO 711.

FIG. 8 illustrates the use of an integrating control path 807, according to the present invention, within a PLL, together with continuous-valued (or analog) proportional control path. In the figure, phase detector 802 provides a continuous-valued (or analog) measure 803 of the phase error between the input signal 801 and the VCO output signal 811. The continuous-valued (or analog) phase detector output is used directly for proportional control and is quantized by analog to digital converter 804 for application to the integral control path 807, which has output 808. The quantization may be binary-valued to deliver UP/DOWN signals 806 and 805, as illustrated, or may be multi-bit valued for a multi-bit digital phase error representation. The continuous-valued (or analog) phase error representation may make use of samples of the received waveform, possibly after signal processing for intersymbol interference cancellation. Signals at both 803 and 808 control the VCO 809.

FIG. 9 illustrates the use of an integrating control path 904, according to the present invention, within a PLL, together with digital proportional control path 906. The two control paths making use of the same phase detector 902, which provides a digital measure 903 of the phase error between the input signal 901 and the VCO output signal 909. 903 is connected to integrating control path 904 with output 905 and also to proportion control path 906 with output 907. Signals at both 905 and 907 control the VCO 908.

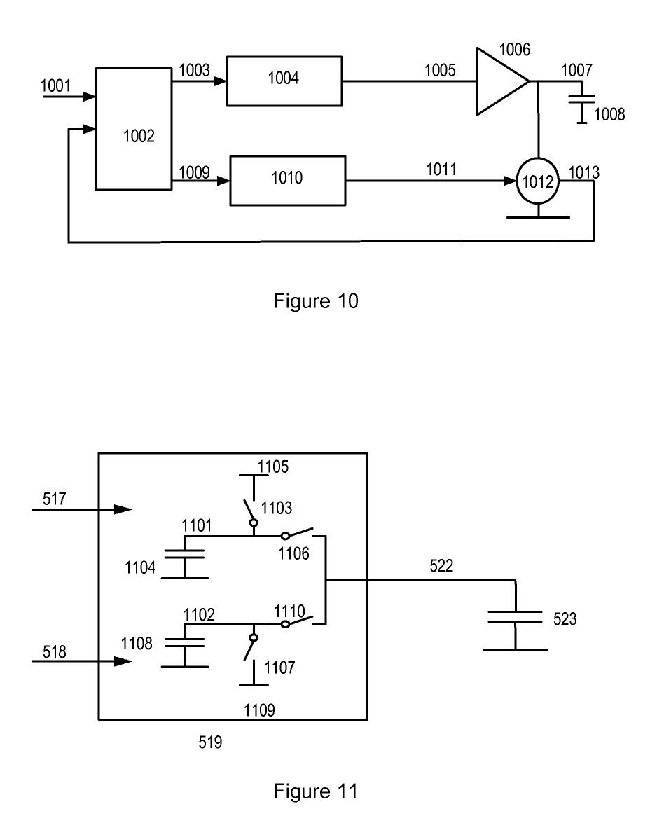

FIG. 10 illustrates the control of a ring oscillator VCO by means of its supply voltage. In the figure supply voltage 1007 to VCO 1012 is provided by a regulator 1006 with smoothing capacitor 1007 and follows the voltage 1005 which is the output of integrating control path according to this invention 1004. Phase detector (or phase detectors) 1002 provides a digital measure 1003 of the phase error between input signal 1001 and VCO output 1013. Signal 1011 from proportional control path 1010 also controls the frequency of the VCO.

The principle and mode of operation of this invention have been explained and illustrated in its preferred embodiment. However, it must be understood that this invention may be practiced otherwise than as specifically explained and illustrated without departing from its spirit or scope.

What is claimed is:

1. A phase-locked loop, comprising a controlled oscillator having an integral control path comprising:
an input for a sequence of digital representations of phase error,
digital logic,
a charge pump circuit, and
an integrating capacitor, wherein a voltage on the integrating capacitor may be used to control an output frequency of the controlled oscillator, and
wherein the digital logic is configured to compute resultant sums of the digital representations of phase error measured over successive time intervals, and the charge pump circuit is configured to charge or discharge the integrating capacitor according to successive resultant sum values.

2. A phase-locked loop according to claim 1, wherein the digital representations of phase error comprise binary valued up and down voting signals.

3. A phase-locked loop according to claim 2, comprising a pair of digital divider circuits for dividing said up and said down voting signals respectively, such that the digital logic is configured to accumulate the digital divider outputs, treated as signals of opposite sign, over the successive time intervals to compute the resultant sum values.

4. A phase-locked loop according to claim 1, wherein said charge pump is adapted to charge and discharge the integrating capacitor according to the sign of said successive resultant sum values.

5. A phase-locked loop according to claim 1, wherein the charge pump comprises switched current sources for charging and discharging the integrating capacitor according to the successive resultant sum values.

6. A phase-locked loop according to claim 5, wherein the switched current sources are adapted to charge and discharge the integrating capacitor according to polarities of the successive resultant sum values, and for durations of time proportional to magnitudes of the successive resultant sum values.

7. A phase-locked loop according to claim 1, wherein the charge pump comprises a switched capacitor circuit, comprising at least one additional capacitance, which is switched to transfer charge to or from the integrating capacitor, according to the successive resultant sum values.

8. A phase-locked loop according to claim 7, wherein said switched capacitor circuits comprises a capacitance with a connection that is switched between the integrating capacitor and to a node of higher voltage and a capacitance with a connection that is switched between the integrating capacitor and to a node of lower voltage.

9. A phase-locked loop according to claim 7, wherein the said switched capacitor circuits are adapted to charge and discharge the integrating capacitor according to the signs of the successive resultant sum values, and for a number of charging or discharging cycles according to the magnitudes of the successive resultant sum values.

10. A phase-locked loop according to claim 1, having a proportional control path, wherein the proportional control path makes use of a digital representation of phase errors.

11. A phase-locked loop according to claim 1, having a proportional control path, wherein the proportional control path makes use of an analog representation of phase errors.

12. A phase-locked loop according to claim 11, comprising a phase detector, in which a waveform is sampled to provide a voltage value for said analog representation of phase error.

13. A phase-locked loop according to claim 11, wherein signal pulse durations are used for said analog representation of phase error.

14. A phase-locked loop according to claim 11, comprising first and second phase detectors for generating separate representations of phase error for integral control and proportional control respectively.

15. A phase-locked loop according to claim 11, comprising a phase detector for providing an analog representation of phase error, and an analog to digital converter to provide said digital representations of phase error.

16. A phase-locked loop according to claim 1, wherein the integrating capacitor is connected to the controlled oscillator such that the integrating capacitor voltage forms a supply voltage for the controlled oscillator.

17. A receiver, for receiving a wanted signal, comprising a phase-locked loop, and a phase detector, for generating a sequence of digital representations of phase error between the wanted signal and an output of the phase locked loop, wherein the phase locked loop comprises a controlled oscillator, having an integral control path comprising:
an input for the sequence of digital representations of phase error,
digital logic,
a charge pump circuit, and
an integrating capacitor, wherein a voltage on the integrating capacitor may be used to control an output frequency of the controlled oscillator, and
wherein the digital logic is configured to compute resultant sums of the digital representations of phase error measured over successive time intervals, and the charge pump circuit is configured to charge or discharge the integrating capacitor according to successive resultant sum values.

18. A frequency multiplier, having an input for receiving a clock signal, and comprising a phase-locked loop, and a phase detector, for generating a sequence of digital representations of phase error between the clock signal and a frequency-divided output of the phase locked loop, wherein the phase locked loop comprises a controlled oscillator, having an integral control path comprising:
an input for the sequence of digital representations of phase error,
digital logic,
a charge pump circuit, and
an integrating capacitor, wherein a voltage on the integrating capacitor may be used to control an output frequency of the controlled oscillator, and
wherein the digital logic is configured to compute resultant sums of the digital representations of phase error measured over successive time intervals, and the charge pump circuit is configured to charge or discharge the integrating capacitor according to successive resultant sum values.
